(19) United States
(12) Patent Application Publication
(10) Pub. No.: US 2019/0225842 A1
(43) Pub. Date: Jul. 25, 2019

(54) OPTICAL ADHESIVE LAYER, MANUFACTURING METHOD OF OPTICAL ADHESIVE LAYER, OPTICAL FILM WITH ADHESIVE LAYER, AND IMAGE DISPLAY DEVICE

(71) Applicant: NITTO DENKO CORPORATION, Ibaraki-shi, Osaka (JP)

(72) Inventors: Tomoyuki Kimura, Ibaraki-shi (JP); Hirotomo Ono, Ibaraki-shi (JP); Akiko Sugino, Ibaraki-shi (JP); Yusuke Toyama, Ibaraki-shi (JP)

(73) Assignee: NITTO DENKO CORPORATION, Ibaraki-shi, Osaka (JP)

(21) Appl. No.: 16/337,019

(22) PCT Filed: Sep. 27, 2017
(86) PCT No.: PCT/JP2017/034992

§ 371 Date: Mar. 27, 2019

(30) Foreign Application Priority Data
Sep. 30, 2016 (JP) 2016-194529

(51) Int. Cl. C09J 7/38; C09J 133/06; C09J 11/06; C09J 133/26

(52) U.S. Cl. CPC C09J 7/385; C09J 133/066; C08K 5/14; C09J 133/26; C09J 11/06

(57) ABSTRACT

The purpose of the present invention is to provide: an optical pressure-sensitive adhesive layer which can suppress the occurrence of foaming, peeling, lifting or the like on an adherend (an optical film) under heating and humidification conditions, and which has high adhesion reliability and excellent durability at high temperatures; a pressure-sensitive adhesive layer attached optical film, having the aforementioned optical pressure-sensitive adhesive layer on at least one surface of the optical film; and further a liquid crystal display device using the aforementioned pressure-sensitive adhesive layer attached optical film. An optical pressure-sensitive adhesive layer formed from a pressure-sensitive adhesive composition containing a (meth)acrylic polymer, wherein the optical pressure-sensitive adhesive layer has a gel fraction of 70% or more and a creep value of 55 μm or more when a load of 500 g is applied to the optical pressure-sensitive adhesive layer for 1 hour under an environment of 115° C.

### TECHNICAL FIELD

The present invention relates to an optical pressure-sensitive adhesive layer, a method for producing an optical pressure-sensitive adhesive layer, and a pressure-sensitive adhesive layer attached optical film having the optical pressure-sensitive adhesive layer on at least one side of an optical film. Furthermore, the present invention relates to an image display device using the pressure-sensitive adhesive layer attached optical film, such as a liquid crystal display device, an organic EL display device, and a PDP. As the optical film, a polarizing film (a polarizing plate), a retardation film, an optical compensation film, a brightness enhancement film, and a laminate thereof can be used.

### BACKGROUND ART

In a liquid crystal display device or the like, it is indispensable to dispose polarizing elements on both sides of a liquid crystal cell from the image forming method, and generally polarizing films are bonded thereto. In addition to polarizing films, various optical elements for improving the display quality of displays have come into use in liquid crystal panels. For example, retardation films for preventing discoloration, viewing angle expansion films for improving the viewing angle of liquid crystal displays, and brightness enhancement films for improving the contrast of displays are used. These films are collectively called optical films.

In general, a pressure-sensitive adhesive is used to bond an optical member such as the optical film to a liquid crystal cell. In order to reduce optical losses, the optical film and the liquid crystal cell or the optical films are generally bonded together with a pressure-sensitive adhesive. In such a case, the pressure-sensitive adhesive is provided in advance as a pressure-sensitive adhesive layer on one side of the optical film, and the resulting pressure-sensitive adhesive layer attached optical film is generally used because it has some advantages such as no need for a drying process to fix the optical film. In general, a release film is attached to the pressure-sensitive adhesive layer of the pressure-sensitive adhesive layer attached optical film.

The required properties required for the pressure-sensitive adhesive layer include high durability under heating/humidification conditions in a state in which the pressure-sensitive adhesive layer is stuck to an optical film and in a state in which the pressure-sensitive adhesive layer attached optical film is bonded to a glass substrate of a liquid crystal panel. For example, in a durability test under heating and humidification conditions etc. commonly conducted as an environment promotion test, high adhesion reliability and the like that no defects such as foaming, peeling, lifting, etc. caused by the pressure-sensitive adhesive layer occur are required.

In addition, an optical film (for example, a polarizing film) tends to shrink due to heat treatment, and there is a problem such that a pressure-sensitive adhesive layer itself is also deformed due to shrinkage of the polarizing film.

In particular, a pressure-sensitive adhesive layer or a pressure-sensitive adhesive layer attached optical films used for outdoor use and used for automotive displays such as car navigation and mobile phones that are supposed to be inside of a high temperature car, are required to have high adhesion reliability and durability at high temperatures.

Various pressure-sensitive adhesive compositions for forming a pressure-sensitive adhesive layer of the pressure-sensitive adhesive layer attached optical film have been proposed (for example, Patent Document 1).

### PRIOR ART DOCUMENT

### Patent Document

Patent Document 1: JP-A-2012-158702

### SUMMARY OF THE INVENTION

### Problems to be Solved by the Invention

In Patent Document 1, a pressure-sensitive adhesive composition obtained by blending 4 to 20 parts by weight of an isocyanate-based crosslinking agent based on 100 parts by weight of an acrylic polymer containing a polar monomer such as an aromatic ring-containing monomer and an amide group-containing monomer has been proposed. However, since the pressure-sensitive adhesive composition of Patent Document 1 has a high blending ratio of the crosslinking agent, peeling tends to occur easily in a durability test, and in particular, such composition does not satisfy adhesion reliability, which is required for in-vehicle use, at high temperatures.

Accordingly, an object of the present invention is to provide an optical pressure-sensitive adhesive layer that is excellent in durability on an adherend in which foaming, peeling or the like does not occur under heating and humidification conditions.

Another object of the present invention is to provide a method for producing the optical pressure-sensitive adhesive layer and a pressure-sensitive adhesive layer attached optical film having the optical pressure-sensitive adhesive layer, and further to provide an image display device using the pressure-sensitive adhesive layer attached optical film.

### Means for Solving the Problems

As a result of extensive studies to solve the above problems, the present inventors have found the following optical pressure-sensitive adhesive layer and have completed the present invention.

That is, the optical pressure-sensitive adhesive layer of the present invention is characterized by an optical pressure-sensitive adhesive layer formed from a pressure-sensitive adhesive composition containing a (meth)acrylic polymer and the optical pressure-sensitive adhesive layer has a gel fraction of 70% or more and a creep value of 55 μm or more when a load of 500 g is applied to the optical pressure-sensitive adhesive layer for 1 hour under an environment of 115° C.

In the optical pressure-sensitive adhesive layer of the present invention, a polydispersity (weight average molecular weight (Mw)/number average molecular weight (Mn)) of the (meth)acrylic polymer is preferably 3.0 or less.

In the optical pressure-sensitive adhesive layer of the present invention, a weight average molecular weight (Mw) of the (meth)acrylic polymer is preferably 900,000 to 3,000,000.

In the optical pressure-sensitive adhesive layer of the present invention, it is preferable that the pressure-sensitive adhesive composition contains a peroxide-based crosslinking agent.

The optical pressure-sensitive adhesive layer of the present invention preferably contains 0.01 to 3 parts by weight of the crosslinking agent per 100 parts by weight of the (meth)acrylic polymer.

In the optical pressure-sensitive adhesive layer of the present invention, it is preferable that the (meth)acrylic polymer contains 0.01 to 7% by weight of a hydroxyl group-containing monomer as a monomer unit.

In the optical pressure-sensitive adhesive layer of the present invention, it is preferable that the (meth)acrylic polymer contains 3 to 25% by weight of an aromatic ring-containing monomer as a monomer unit.

In the optical pressure-sensitive adhesive layer of the present invention, it is preferable that the (meth)acrylic polymer contains 0.1 to 20% by weight of an amide group-containing monomer as a monomer unit.

In the optical pressure-sensitive adhesive layer of the present invention, it is preferable that the amide group-containing monomer is an N-vinyl group-containing lactam-based monomer.

In the optical pressure-sensitive adhesive layer of the present invention, it is preferable that the pressure-sensitive adhesive composition contains an organic tellurium compound.

The method for producing an optical pressure-sensitive adhesive layer of the present invention is the method for producing an optical pressure-sensitive adhesive layer described above, and it is preferable to produce the (meth)acrylic polymer by living radical polymerization.

The pressure-sensitive adhesive layer attached optical film according to the present invention preferably has the optical pressure-sensitive adhesive layer on at least one side of an optical film.

In the pressure-sensitive adhesive layer attached optical film according to the present invention, it is preferable that the optical film is a polarizing film; the polarizing film includes a polarizer; and the polarizer has a thickness of 30 μm or less.

In the image display device of the present invention, it is preferable that at least one pressure-sensitive adhesive layer attached optical film is used.

### Effect of the Invention

The optical pressure-sensitive adhesive layer of the present invention is characterized by an optical pressure-sensitive adhesive layer formed from a pressure-sensitive adhesive composition containing a (meth)acrylic polymer and the optical pressure-sensitive adhesive layer has a gel fraction of 70% or more and a creep value of 55 μm or more when a load of 500 g is applied to the optical pressure-sensitive adhesive layer for 1 hour under an environment of 115° C. Even when the optical pressure-sensitive adhesive layer is exposed to heating/humidifying conditions in a state of being attached to an optical film, occurrence of foaming, peeling, lifting, etc. can be suppressed, and high adhesion reliability and durability at high temperature can be obtained, which is useful.

### BRIEF DESCRIPTION OF THE DRAWINGS

FIG. 1 is an example of a schematic cross-sectional view of a pressure-sensitive adhesive layer attached polarizing film according to the present invention.

### MODE FOR CARRYING OUT THE INVENTION

### <(Meth)Acrylic Polymer>

The optical pressure-sensitive adhesive layer of the present invention is characterized by being formed from a pressure-sensitive adhesive composition containing a (meth)acrylic polymer. The (meth)acrylic polymer usually contains an alkyl (meth)acrylate monomer unit as a main component. Incidentally, the term “(meth)acrylate” refers to acrylate and/or methacrylate, and the term “(meth)” is used in the same meaning in the present invention.

As the alkyl (meth)acrylate forming the main skeleton of the (meth)acrylic polymer, a linear or branched alkyl group having 1 to 18 carbon atoms can be exemplified. Examples of such alkyl group include methyl, ethyl, propyl, isopropyl, butyl, isobutyl, amyl, hexyl, cyclohexyl, heptyl, 2-ethylhexyl, isooctyl, nonyl, decyl, isodecyl, dodecyl, isomyristyl, lauryl, tridecyl, pentadecyl, hexadecyl, heptadecyl, and octadecyl groups, and the like. These can be used alone or in combination. The average number of carbon atoms of these alkyl groups is preferably from 3 to 9.

It is preferable that the (meth)acrylic polymer contains a hydroxyl group-containing monomer as a monomer unit. The hydroxyl group-containing monomer is preferably a compound containing a hydroxyl group in its structure and containing a polymerizable unsaturated double bond such as a (meth)acryloyl group or a vinyl group. Specific examples of the hydroxyl group-containing monomer include hydroxyalkyl (meth)acrylates such as 2-hydroxyethyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, and 12-hydroxylauryl (meth)acrylate, and (4-hydroxymethylcyclohexyl)-methylacrylate. Among the hydroxyl group-containing monomers, from the viewpoint of durability, 2-hydroxyethyl (meth)acrylate and 4-hydroxybutyl (meth)acrylate are preferable, and 4-hydroxybutyl (meth)acrylate is particularly preferable.

It is preferable that the (meth)acrylic polymer contains an aromatic ring-containing monomer as a monomer unit. The aromatic ring-containing monomer is preferably a compound containing an aromatic ring structure in its structure and containing a (meth)acryloyl group (hereinafter sometimes referred to as an aromatic ring-containing (meth)acrylate). The aromatic ring may be a benzene ring, a naphthalene ring, or a biphenyl ring. The aromatic ring-containing (meth)acrylate can provide a satisfactory level of durability (particularly, durability against an ITO layer which is a transparent conductive layer) and improve display unevenness caused by peripheral white voids.

Specific examples of the aromatic ring-containing monomer include styrene, p-tert-butoxystyrene, and p-acetoxystyrene.

Specific examples of the aromatic ring-containing (meth)acrylate include benzene ring-containing (meth)acrylates such as benzyl (meth)acrylate, phenyl (meth)acrylate, o-phenylphenol (meth)acrylate, phenoxy (meth)acrylate, phenoxyethyl (meth)acrylate, phenoxypropyl (meth)acrylate, phenoxydiethylene glycol (meth)acrylate, ethylene oxide modified nonylphenol (meth)acrylate, ethylene oxide modified cresol (meth)acrylate, phenol ethylene oxide modified (meth)acrylate, 2-hydroxy-3-phenoxypropyl (meth)acrylate, methoxybenzyl (meth)acrylate, chlorobenzyl (meth)acrylate, cresyl (meth)acrylate, and polystyryl (meth)acrylate; naphthalene ring-containing (meth)acrylates such as hydroxyethylated-naphthol acrylate, 2-naphthoethyl (meth)acrylate, 2-naphthoxyethyl acrylate, and 2-(4-methoxy-1-naphthoxy)ethyl (meth)acrylate; and biphenyl ring-containing (meth)acrylates such as biphenyl (meth)acrylate.

As the aromatic ring-containing (meth)acrylate, from the viewpoints of adhesive properties and durability, benzyl (meth)acrylate and phenoxyethyl (meth)acrylate are preferable, and phenoxyethyl (meth)acrylate is particularly preferable.

It is preferable that the (meth)acrylic polymer contains an amide group-containing monomer as a monomer unit. The amide group-containing monomer is preferably a compound having an amide group in its structure and also having a polymerizable unsaturated double bond such as a (meth)acryloyl group and a vinyl group. Specific examples of the amide group-containing monomer include acrylamide monomers such as (meth)acrylamide, N,N-dimethyl (meth)acrylamide, N,N-diethyl (meth)acrylamide, N-isopropyl acrylamide, N-methyl (meth)acrylamide, N-butyl (meth)acrylamide, N-hexyl (meth)acrylamide, N-methylol (meth)acrylamide, N-methylol-N-propane (meth)acrylamide, aminomethyl (meth)acrylamide, aminoethyl (meth)acrylamide, mercaptomethyl (meth)acrylamide, and mercaptoethyl (meth)acrylamide; N-acryloyl heterocyclic monomers such as N-(meth)acryloylmorpholine, N-(meth)acryloylpiperidine, and N-(meth)acryloylpyrrolidine; and N-vinyl group-containing lactam-based monomers such as N-vinylpyrrolidone and N-vinyl-ε-caprolactam. The amide group-containing monomers are preferred in terms of satisfying durability and among the amide group-containing monomers, N-vinyl group-containing lactam-based monomers are particularly preferable from the viewpoint of satisfying durability against an ITO layer and reworkability.

When the pressure-sensitive adhesive composition contains a crosslinking agent, these copolymerizable monomers can provide reactive points to the crosslinking agent. The hydroxyl group-containing monomer, which is highly reactive with an intermolecular crosslinking agent, is preferably used to improve cohesiveness or heat resistance of the resulting pressure-sensitive adhesive layer. The hydroxyl group-containing monomer is also preferable from the viewpoint of reworkability.

The (meth)acrylic polymer contains a predetermined amount of each monomer as a monomer unit on a weight ratio basis with respect to all the constituent monomers (100% by weight).

The weight ratio of the alkyl (meth)acrylate can be set as the balance of monomers other than the alkyl (meth)acrylate. Specifically, the weight ratio of the alkyl (meth)acrylate is preferably 60% by weight or more, more preferably 65 to 99.8% by weight, even more preferably 70 to 99.6% by weight. It is preferable to set the weight ratio of the alkyl (meth)acrylate within the above range in order to secure adhesion property.

The weight ratio of the hydroxyl group-containing monomer is preferably 0.01 to 7% by weight, more preferably 0.1 to 6% by weight, even more preferably 0.3 to 5% by weight. When the weight ratio of the hydroxyl group-containing monomer is less than 0.01% by weight, the pressure-sensitive adhesive layer becomes insufficient in crosslinking and may not satisfy the durability and adhesive properties. On the other hand, when the weight ratio of the hydroxyl group-containing monomer exceeds 7% by weight, the pressure-sensitive adhesive layer may not satisfy the durability.

The weight ratio of the aromatic ring-containing monomer is preferably 3 to 25% by weight, more preferably 8 to 22% by weight, even more preferably 12 to 18% by weight. When the weight ratio of the aromatic ring-containing monomer is within the above range, display unevenness due to light leakage can be sufficiently suppressed and durability is excellent, which is preferable. When the weight ratio of the aromatic ring-containing monomer exceeds 25% by weight, the display unevenness is, on the contrary, not sufficiently suppressed and the durability is also lowered.

The weight ratio of the amide group-containing monomer is preferably from 0.1 to 20% by weight, more preferably from 0.3 to 10% by weight, even more preferably from 0.3 to 8% by weight, particularly preferably from 0.7 to 6% by weight %. When the weight ratio of the amide group-containing monomer is within the above range, the durability against an ITO layer can be particularly satisfied. If the weight ratio of the amide group-containing monomer exceeds 20% by weight, such durability is lowered, and such a weight ratio of exceeding 20% by weight is not preferable from the viewpoint of reworkability.

The (meth)acrylic polymer does not need to contain any other monomer unit than the monomer units described above. In order to improve adhesion property and heat resistance, however, one or more copolymerizable monomers having an unsaturated double bond-containing polymerizable functional group, such as a (meth)acryloyl group or a vinyl group, may be introduced into the polymer by copolymerization.

Specific examples of such copolymerizable monomers include acid anhydride group-containing monomers such as maleic anhydride and itaconic anhydride; caprolactone adducts of acrylic acid; sulfonic acid group-containing monomers such as allylsulfonic acid, 2-(meth)acrylamido-2-methylpropane sulfonic acid, (meth)acrylamidopropane sulfonic acid, and sulfopropyl (meth)acrylate; and phosphate group-containing monomers such as 2-hydroxyethylacryloyl phosphate.

Examples of such monomers for modification also include alkylaminoalkyl (meth)acrylates such as aminoethyl (meth)acrylate, N,N-dimethylaminoethyl (meth)acrylate, and tert-butylaminoethyl (meth)acrylate; alkoxyalkyl (meth)acrylates such as methoxyethyl (meth)acrylate and ethoxyethyl (meth)acrylate; succinimide monomers such as N-(meth)acryloyloxymethylenesuccinimide, N-(meth)acryloyl-6-oxyhexamethylenesuccinimide, and N-(meth)acryloyl-8-oxyoctamethylenesuccinimide; maleimide monomers such as N-cyclohexylmaleimide, N-isopropylmaleimide, N-laurylmaleimide, and N-phenylmaleimide; and itaconimide monomers such as N-methylitaconimide, N-ethylitaconimide, N-butylitaconimide, N-octylitaconimide, N-2-ethylhexylitaconimide, N-cyclohexylitaconimide, and N-laurylitaconimide.

Examples of modifying monomers that may also be used include vinyl monomers such as vinyl acetate and vinyl propionate; cyanoacrylate monomers such as acrylonitrile and methacrylonitrile; epoxy group-containing (meth)acrylates such as glycidyl (meth)acrylate; glycol (meth)acrylates such as polyethylene glycol (meth)acrylate, polypropylene glycol (meth)acrylate, methoxyethylene glycol (meth)acrylate, and methoxypolypropylene glycol (meth)acrylate; and (meth)acrylate monomers such as tetrahydrofurfuryl (meth)acrylate, fluoro (meth)acrylate, silicone (meth)acrylate, and 2-methoxyethyl acrylate. Further, isoprene, butadiene, isobutylene, vinyl ether and the like can be exemplified.

Besides the above, a silicon atom-containing silane monomer may be exemplified as the copolymerizable monomer. Examples of the silane monomers include
3-acryloxypropyltriethoxysilane, vinyltrimethoxysilane, vinyltriethoxysilane, 4-vinylbutyltrimethoxysilane,
4-vinylbutyltriethoxysilane, 8-vinyloctyltrimethoxysilane,
8-vinyloctyltriethoxysilane,
10-methacryloyloxydecyltrimethoxysilane,
10-acryloyloxydecyltrimethoxysilane,
10-methacryloyloxydecyltriethoxysilane, and
10-acryloyloxydecyltriethoxysilane.

Copolymerizable monomers that may be used also include polyfunctional monomers having two or more unsaturated double bonds such as (meth)acryloyl groups or vinyl groups, which include (meth)acrylate esters of polyhydric alcohols, such as tripropylene glycol di(meth)acrylate, tetraethylene glycol di(meth)acrylate, 1,6-hexanediol di(meth)acrylate, bisphenol A diglycidyl ether di(meth)acrylate, neopentyl glycol di(meth)acrylate, trimethylolpropane tri(meth)acrylate, pentaerythritol tri(meth)acrylate, pentaerythritol tetra(meth)acrylate, dipentaerythritol penta(meth)acrylate, dipentaerythritol hexa(meth)acrylate, and caprolactone-modified dipentaerythritol hexa(meth)acrylate; and compounds having a polyester, epoxy or urethane skeleton to which two or more unsaturated double bonds are added in the form of functional groups such as (meth)acryloyl groups or vinyl groups in the same manner as the monomer component, such as polyester (meth)acrylates, epoxy (meth)acrylates and urethane (meth)acrylates.

The proportion of the copolymerizable monomer in the (meth)acrylic polymer is preferably about 0 to 10%, more preferably about 0 to 7%, even more preferably about 0 to 5% on the weight ratio basis with respect to all the constituent monomers (100% by weight) of the (meth)acrylic polymer.

It is preferable that the (meth)acrylic polymer does not contain a carboxyl group-containing monomer as a monomer unit. When the carboxyl group-containing monomer is contained, durability (for example, metal corrosion resistance) may not be satisfied in some cases, and such a carboxyl group-containing monomer is also undesirable from the viewpoint of reworkability. When the carboxyl group-containing monomer is used, the carboxyl group-containing monomer is preferably a compound containing a carboxyl group in its structure and containing a polymerizable unsaturated double bond such as a (meth)acryloyl group and a vinyl group. Specific examples of such carboxyl group-containing monomer include (meth)acrylic acid, carboxyethyl (meth)acrylate, carboxypentyl (meth)acrylate, itaconic acid, maleic acid, fumaric acid, crotonic acid, and the like. Among the carboxyl group-containing monomers, acrylic acid is preferable from the viewpoints of copolymerizability, cost, and adhesive properties.

The weight average molecular weight (Mw) of the (meth)acrylic polymer is preferably 900,000 to 3,000,000. In consideration of durability, particularly heat resistance, such weight average molecular weight is more preferably from 1,200,000 to 2,500,000. When the weight average molecular weight of the (meth)acrylic polymer is less than 900,000, the low molecular weight polymer component increases and the crosslinking density of the gel (pressure sensitive adhesive layer) increases, with the result that the pressure sensitive adhesive layer becomes hard and the stress relaxation property is impaired, which is not preferable. On the other hand, when the weight average molecular weight is larger than 3,000,000, viscosity of the polymer increases and gelation occurs during polymerization of the polymer, which is not preferable.

The polydispersity (weight average molecular weight (Mw)/number average molecular weight (Mn)) of the (meth)acrylic polymer is preferably 3.0 or less, more preferably 1.05 to 2.5, even more preferably 1.05 to 2.0. When the polydispersity (Mw/Mn) exceeds 3.0, the number of low molecular weight polymers increases, and in order to increase the gel fraction of the pressure-sensitive adhesive layer, it is necessary to use a large amount of a crosslinking agent. Thereby, an excessive crosslinking agent reacts with the already gelled polymer to increase the crosslinking density of the gel (pressure-sensitive adhesive layer), and accompanying this, the pressure-sensitive adhesive layer becomes hard and the stress relaxation property is impaired, which is not preferable. In addition, when many low molecular weight polymers are present and uncrosslinked polymers and oligomers (sol contents) are increased, it is presumed that breakage of the pressure-sensitive adhesive layer occurs under heating and humidification conditions, causing peeling of the pressure-sensitive adhesive layer by the uncrosslinked polymer or the like segregated in the vicinity of the interface of the pressure-sensitive adhesive layer in contact with an adherend (for example, ITO or the like). As a result, it is preferable that the polydispersity (Mw/Mn) is adjusted to 3.0 or less. The weight average molecular weight and the polydispersity (Mw/Mn) are values calculated from polystyrene equivalent values determined by gel permeation chromatography (GPC).

For the production of such a (meth)acrylic polymer, any appropriate method may be selected from known production methods such as solution polymerization, bulk polymerization, emulsion polymerization, and various radical polymerization. Among them, from the viewpoints of convenience and versatility, the solution polymerization is preferable. A living radical polymerization is also preferable from the viewpoint that production of low molecular weight oligomers can be suppressed, and productivity can be ensured even when the polymerization rate is increased. In addition, the obtained (meth)acrylic polymer may be any type of a random copolymer, a block copolymer, a graft copolymer and the like.

In the solution polymerization, for example, ethyl acetate, toluene or the like is used as a polymerization solvent. In a specific solution polymerization, for example, the reaction is performed under a stream of inert gas such as nitrogen at a temperature of about 50 to 70° C. for about 10 minutes to 30 hours in the presence of a polymerization initiator. In particular, by shortening the polymerization time to about 30 minutes to 3 hours, adhesion reliability of the pressure-sensitive adhesive can be improved by suppressing the formation of low molecular weight oligomers generated in the later stage of polymerization.

The polymerization initiators, chain transfer agents, emulsifiers and the like used for the radical polymerization are not particularly limited and can be appropriately selected and used. The weight average molecular weight of the (meth)acrylic polymer can be controlled by the amount of the polymerization initiator and the chain transfer agent used, and the reaction conditions, and the amount used thereof is appropriately adjusted according to these types.

### <Polymerization Initiator>

Examples of the polymerization initiator include, but are not limited to, azo-based initiators such as 2,2′-azobisisobutylonitrile, 2,2′-azobis(2-amidinopropane) dihydrochloride, 2,2′-azobis[2-(5-methyl-2-imidazolin-2-yl)propane]dihydrochloride, 2,2′-azobis(2-methylpropionamidine) disulfate, 2,2′-azobis(N,N′-dimethyleneisobutylamidine), and 2,2′-azobis[N-(2-carboxyethyl)-2-methylpropionamidine]hydrate (VA-057, manufactured by Wako Pure Chemical Industries, Ltd.); persulfates such as potassium persulfate and ammonium persulfate; peroxide-based initiators such as di(2-ethylhexyl)peroxydicarbonate, di(4-tert-butylcyclohexyl)peroxydicarbonate, di-sec-butylperoxydicarbonate, tert-butylperoxyneodecanoate, tert-hexylperoxypivalate, tert-butylperoxypivalate, dilauroyl peroxide, di-n-octanoyl peroxide, 1,1,3,3-tetramethylbutylperoxy-2-ethyl hexanoate, di(4-methylbenzoyl) peroxide, dibenzoyl peroxide, tert-butylperoxyisobutylate, 1,1-di(tert-hexylperoxy)cyclohexane, tert-butylhydroperoxide, and hydrogen peroxide; and redox system initiators of a combination of a peroxide and a reducing agent, such as a combination of a persulfate and sodium hydrogen sulfite and a combination of a peroxide and sodium ascorbate. Also, as a polymerization initiator used for living radical polymerization, there are exemplified organic tellurium compounds including, for example,
(methyltellanyl-methyl)benzene,
(1-methyltellanyl-ethyl)benzene,
(2-methyltellanyl-propyl)benzene,
1-chloro-4-(methyltellanyl-methyl)benzene,
1-hydroxy-4-(methyltellanyl-methyl)benzene,
1-methoxy-4-(methyltellanyl-methyl)benzene,
1-amino-4-(methyltellanyl-methyl)benzene,
1-nitro-4-(methyltellanyl-methyl)benzene,
1-cyano-4-(methyltellanyl-methyl)benzene,
1-methylcarbonyl-4-(methyltellanyl-methyl)benzene,
1-phenylcarbonyl-4-(methyltellanyl-methyl)benzene,
1-methoxycarbonyl-4-(methyltellanyl-methyl)benzene,
1-phenoxycarbonyl-4-(methyltellanyl-methyl)benzene,
1-sulfonyl-4-(methyltellanyl-methyl)benzene,
1-trifluoromethyl-4-(methyltellanyl-methyl)benzene,
1-chloro-4-(1-methyltellanyl-ethyl)benzene,
1-hydroxy-4-(1-methyltellanyl-ethyl)benzene,
1-methoxy-4-(1-methyltellanyl-ethyl)benzene,
1-amino-4-(1-methyltellanyl-ethyl)benzene,
1-nitro-4-(1-methyltellanyl-ethyl)benzene,
1-cyano-4-(1-methyltellanyl-ethyl)benzene,
1-methylcarbonyl-4-(1-methyltellanyl-ethyl)benzene,
1-phenylcarbonyl-4-(1-methyltellanyl-ethyl)benzene,
1-methoxycarbonyl-4-(1-methyltellanyl-ethyl)benzene,
1-phenoxycarbonyl-4-(1-methyltellanyl-ethyl)benzene,
1-sulfonyl-4-(1-methyltellanyl-ethyl)benzene,
1-trifluoromethyl-4-(1-methyltellanyl-ethyl)benzene,
1-chloro-4-(2-methyltellanyl-propyl)benzene,
1-hydroxy-4-(2-methyltellanyl-propyl)benzene,
1-methoxy-4-(2-methyltellanyl-propyl)benzene,
1-amino-4-(2-methyltellanyl-propyl)benzene,
1-nitro-4-(2-methyltellanyl-propyl)benzene,
1-cyano-4-(2-methyltellanyl-propyl)benzene,
1-methylcarbonyl-4-(2-methyltellanyl-propyl)benzene,
1-phenylcarbonyl-4-(2-methyltellanyl-propyl)benzene,
1-methoxycarbonyl-4-(2-methyltellanyl-propyl)benzene,
1-phenoxycarbonyl-4-(2-methyltellanyl-propyl)benzene,
1-sulfonyl-4-(2-methyltellanyl-propyl)benzene,
1-trifluoromethyl-4-(2-methyltellanyl-propyl)benzene,
2-(methyltellanyl-methyl)pyridine,
2-(1-methyltellanyl-ethyl)pyridine,
2-(2-methyltellanyl-propyl)pyridine, methyl
2-methyltellanyl-ethanoate, methyl
2-methyltellanyl-propionate, methyl
2-methyltellanyl-2-methylpropionate, ethyl
2-methyltellanyl-ethanoate, ethyl
2-methyltellanyl-propionate, ethyl
2-methyltellanyl-2-methylpropionate, 2-methyltellanyl acetonitrile, 2-methyltellanyl propionitrile,
   2-methyl-2-methyltellanyl propionitrile, and the like. The methyltellanyl group in these organotellurium compounds may be substituted with an ethyltellanyl group, an n-propyltellanyl group, an isopropyltellanyl group, an n-butyltellanyl group, an isobutyltellanyl group, a t-butyltellanyl group, a phenyltellanyl group or the like.

The polymerization initiator may be used alone or as a mixture of two or more kinds thereof, but the content as a whole is preferably about 0.005 to 1 part by weight, more preferably about 0.02 to 0.5 parts by weight, per 100 parts by weight of the total amount of the monomer components.

Incidentally, in order to prepare a (meth)acrylic polymer having the weight average molecular weight (Mw) and the polydispersity (Mw/Mn) described above, the polymerization initiator, for example, 2,2′-azobisisobutyronitrile is used in an amount of preferably about 0.06 to 0.2 parts by weight, more preferably about 0.08 to 0.175 parts by weight, per 100 parts by weight of the total amount of the monomer components.

Examples of the chain transfer agent include lauryl mercaptan, glycidyl mercaptan, mercaptoacetic acid, 2-mercaptoethanol, thioglycolic acid, 2-ethylhexyl thioglycolate, 2,3-dimercapto-1-propanol and the like. The chain transfer agent may be used alone or as a mixture of two or more kinds thereof, but the total content is about 0.1 parts by weight or less per 100 parts by weight of the total amount of the monomer components.

Examples of the emulsifier used in emulsion polymerization include anionic emulsifiers such as sodium lauryl sulfate, ammonium lauryl sulfate, sodium dodecylbenzenesulfonate, ammonium polyoxyethylene alkyl ether sulfate, and sodium polyoxyethylene alkyl phenyl ether sulfate; and nonionic emulsifiers such as polyoxyethylene alkyl ether, polyoxyethylene alkyl phenyl ether, polyoxyethylene fatty acid ester, and polyoxyethylene-polyoxypropylene block polymers. These emulsifiers may be used alone or in combination of two or more kinds thereof.

Further, as the emulsifier, a reactive emulsifier in which a radically polymerizable functional group such as a propenyl group, an allyl ether group or the like is introduced can be used, and specific examples thereof include AQUALON HS-10, HS-20, KH-10, BC-05, BC-10, and BC-20 (each manufactured by Dai-ichi Kogyo Seiyaku Co., Ltd.) and ADEKARIA SOAP SE10N (manufactured by Asahi Denka Kogyo K.K.). The reactive emulsifier is preferred, because after polymerization, it can be incorporated into a polymer chain to improve water resistance. Based on 100 parts by weight of the total monomer components, the emulsifier is used in an amount of preferably 0.3 to 5 parts by weight, more preferably 0.5 to 1 part by weight, in view of polymerization stability or mechanical stability.

### <Crosslinking Agent>

The pressure-sensitive adhesive composition preferably contains a crosslinking agent. As the crosslinking agent, an organic crosslinking agent or a polyfunctional metal chelate (metal chelate-based crosslinking agent) can be used.

Examples of the organic crosslinking agent include an isocyanate-based crosslinking agent, a peroxide-based crosslinking agent, an epoxy-based crosslinking agent, an imine-based crosslinking agent, a carbodiimide-based crosslinking agent and the like. The polyfunctional metal chelate is one in which a polyvalent metal is covalently or coordinately bonded to an organic compound. Examples of the polyvalent metal atom include Al, Cr, Zr, Co, Cu, Fe, Ni, V, Zn, In, Ca, Mg, Mn, Y, Ce, Sr, Ba, Mo, La, Sn, and Ti. The organic compound has a covalent or coordinate bond-forming atom such as an oxygen atom, and examples of the organic compound include an alkyl ester, an alcohol compound, a carboxylic acid compound, an ether compound, a ketone compound, and the like. Use of the crosslinking agent is preferable because cohesive force can be imparted to the pressure-sensitive adhesive and heat resistance can be improved. In particular, by using a peroxide-based crosslinking agent, a high-molecular weight (meth)acrylic polymer can be prepared and a pressure-sensitive adhesive layer having a high gel fraction and an excellent stress relaxation property can be obtained, so that peeling in a durability test can be suppressed, which is preferable.

The isocyanate-based crosslinking agent may be a compound having at least two isocyanate groups. For example, an aliphatic polyisocyanate, an alicyclic polyisocyanate, or an aromatic polyisocyanate known in the art and commonly used for urethane-forming reaction may be used as the isocyanate-based crosslinking agent.

Examples of the aliphatic polyisocyanate include trimethylene diisocyanate, tetramethylene diisocyanate, hexamethylene diisocyanate, pentamethylene diisocyanate, 1,2-propylene diisocyanate, 1,3-butylene diisocyanate, dodecamethylene diisocyanate, 2,4,4-trimethylhexamethylene diisocyanate, and the like.

Examples of the alicyclic isocyanate include 1,3-cyclopentene diisocyanate, 1,3-cyclohexane diisocyanate, 1,4-cyclohexane diisocyanate, isophorone diisocyanate, hydrogenated diphenylmethane diisocyanate, hydrogenated xylylene diisocyanate, hydrogenated tolylene diisocyanate, hydrogenated tetramethylxylylene diisocyanate, and the like.

Examples of the aromatic diisocyanate include phenylene diisocyanate, 2,4-tolylene diisocyanate, 2,6-tolylene diisocyanate, 2,2′-diphenylmethane diisocyanate, 4,4′-diphenylmethane diisocyanate, 4,4′-toluidine diisocyanate, 4,4′-diphenyl ether diisocyanate, 4,4′-diphenyl diisocyanate, 1,5-naphthalene diisocyanate, xylylene diisocyanate, and the like.

Examples of the isocyanate-based crosslinking agent include multimers (such as dimers, trimers, or pentamers) of these diisocyanates, and urethane-modified products formed by the reaction with a polyalcohol such as trimethylolpropane, urea-modified products, biuret-modified products, allophanate-modified products, isocyanurate-modified products, carbodiimide-modified products, and the like.

Commercially available examples of the isocyanate-based crosslinking agent include “MILLIONATE MT”, “MILLIONATE MTL”, “MILLIONATE MR-200”, “MILLIONATE MR-400”, “CORONATE L”, “CORONATE HL”, and “CORONATE HX” (all trade names, manufactured by NIPPON POLYURETHANE INDUSTRY CO., LTD.), and “TAKENATE D-110N”, “TAKENATE D-120N”, “TAKENATE D-140N”, “TAKENATE D-160N”, “TAKENATE D-165N”, “TAKENATE D-170HN”, “TAKENATE D-178N”, “TAKENATE 500”, and “TAKENATE 600” (all trade names, manufactured by Mitsui Chemicals, Inc.). These compounds may be used alone or in combination of two or more kinds thereof.

As the isocyanate-based crosslinking agent, preferred are an aliphatic polyisocyanate and an aliphatic polyisocyanate-based compound that is a modified product thereof. Aliphatic polyisocyanate-based compounds can form a crosslinked structure more flexible than that obtained with other isocyanate crosslinking agents, can easily relax the stress associated with the expansion/shrinkage of optical films, and are less likely to cause peeling in a durability test. In particular, preferred aliphatic polyisocyanate-based compounds include hexamethylene diisocyanate and derivatives thereof.

Any peroxide-based crosslinking agent (sometimes referred to simply as a peroxide) capable of generating active radical species by heating or photoirradiation and promoting the crosslinking of the base polymer ((meth)acrylic polymer) in the pressure-sensitive adhesive composition may be appropriately used. In view of workability and stability, a peroxide with a one-minute half-life temperature of 80° C. to 160° C. is preferably used, and a peroxide with a one-minute half-life temperature of 90° C. to 140° C. is more preferably used.

Examples of the peroxide that can be used include di(2-ethylhexyl) peroxydicarbonate (one-minute half-life temperature: 90.6° C.), di(4-tert-butylcyclohexyl) peroxydicarbonate (one-minute half-life temperature: 92.1° C.), di-sec-butyl peroxydicarbonate (one-minute half-life temperature: 92.4° C.), tert-butyl peroxyneodecanoate (one-minute half-life temperature: 103.5° C.), tert-hexyl peroxypivalate (one-minute half-life temperature: 109.1° C.), tert-butyl peroxypivalate (one-minute half-life temperature: 110.3° C.), dilauroyl peroxide (one-minute half-life temperature: 116.4° C.), di-n-octanoylperoxide (one-minute half-life temperature: 117.4° C.), 1,1,3,3-tetramethylbutylperoxy-2-ethyl hexanoate (one-minute half-life temperature: 124.3° C.), di(4-methylbenzoyl) peroxide (one-minute half-life temperature: 128.2° C.), dibenzoyl peroxide (one-minute half-life temperature: 130.0° C.), tert-butyl peroxyisobutylate (one-minute half-life temperature: 136.1° C.), and 1,1-di(tert-hexylperoxy)cyclohexane (one-minute half-life temperature: 149.2° C.). In particular, di(4-tert-butylcyclohexyl) peroxydicarbonate (one-minute half-life temperature: 92.1° C.), dilauroyl peroxide (one-minute half-life temperature: 116.4° C.), dibenzoyl peroxide (one-minute half-life temperature: 130.0° C.), or the like is preferably used, because they can provide high crosslinking reaction efficiency.

The half-life of the peroxide is an indicator representing the decomposition rate of the peroxide and refers to the time until the remaining amount of the peroxide is halved. The decomposition temperature for obtaining the half-life in arbitrary time and the half-life time obtained at a certain temperature are shown in catalogs furnished by manufacturers, such as “Organic Peroxide Catalog, 9th Edition, May 2003” furnished by NOF CORPORATION.

The amount of decomposition of the peroxide may be determined by measuring the peroxide residue after the reaction process by, for example, HPLC (high performance liquid chromatography).

More specifically, for example, after the reaction process, about 0.2 g of each pressure-sensitive adhesive composition is taken out, immersed in 10 ml of ethyl acetate, subjected to shaking extraction at 25° C. and 120 rpm for 3 hours in a shaker, and then allowed to stand at room temperature for 3 days. Thereafter, 10 ml of acetonitrile is added, and the mixture is shaken at 25° C. and 120 rpm for 30 minutes. About 10 μl of the liquid extract obtained by filtration through a membrane filter (0.45 μm) is subjected to HPLC by injection and analyzed so that the amount of the peroxide after the reaction process is determined.

The amount of the crosslinking agent to be used is preferably 0.01 to 3 parts by weight, more preferably 0.05 to 2 parts by weight, even more preferably 0.1 to 1 part by weight, per 100 parts by weight of the (meth)acrylic polymer. If the amount of the crosslinking agent is less than 0.01 parts by weight, the pressure-sensitive adhesive layer becomes insufficient in crosslinking and there is a possibility that the durability and the adhesive properties may not be satisfied, whereas if the amount of the crosslinking agent exceeds 3 parts by weight, the pressure-sensitive adhesive layer tends to be too hard and the durability tends to decrease.

The pressure-sensitive adhesive composition of the present invention may contain a silane coupling agent. By using the silane coupling agent, the durability can be improved. Specific examples of the silane coupling agent include epoxy group-containing silane coupling agents such as
3-glycidoxypropyltrimethoxysilane,
3-glycidoxypropyltriethoxysilane,
3-glycidoxypropylmethyldiethoxysilane, and
2-(3,4-epoxycyclohexyl)ethyltrimethoxysilane; amino group-containing silane coupling agents such as
3-aminopropyltrimethoxysilane,
N-(2-aminoethyl)-3-aminopropylmethyldimethoxysilane,
3-triethoxysilyl-N-(1,3-dimethylbutylidene)propylamine, and
N-phenyl-γ-aminopropyltrimethoxysilane; (meth)acrylic group-containing silane coupling agents such as
3-acryloxypropyltrimethoxysilane and
3-methacryloxypropyltriethoxysilane; and isocyanate group-containing silane coupling agents such as
3-isocyanatepropyltriethoxysilane. Epoxy group-containing silane coupling agents are preferred among the silane coupling agents listed above.

As the silane coupling agent, one having a plurality of alkoxysilyl groups in the molecule can also be used. Specific examples thereof include X-41-1053, X-41-1059A, X-41-1056, X-41-1805, X-41-1818, X-41-1810, and X-40-2651 manufactured by Shin-Etsu Chemical Co., Ltd. These silane coupling agents having a plurality of alkoxysilyl groups in the molecule are preferable in that they are less volatile and effective in improving durability due to their two or more alkoxysilyl groups. In particular, these silane coupling agents can provide suitable durability also when the adherend on the pressure-sensitive adhesive layer attached optical film is a transparent conductive layer (such as an ITO), which is less reactive with the alkoxysilyl group than glass. The silane coupling agent having a plurality of alkoxysilyl groups in the molecule is preferably one having an epoxy group in the molecule, more preferably one having two or more epoxy groups in the molecule. The silane coupling agent having a plurality of alkoxysilyl groups and an epoxy group(s) in the molecule tends to provide good durability also when the adherend is a transparent conductive layer (such as an ITO). Specific examples of the silane coupling agent having a plurality of alkoxysilyl groups and an epoxy group(s) in the molecule include X-41-1053, X-41-1059A, and X-41-1056 manufactured by Shin-Etsu Chemical Co., Ltd, among which X-41-1056 manufactured by Shin-Etsu Chemical Co., Ltd. is particularly preferred, which has a high epoxy group content.

The silane coupling agents may be used alone, or a mixture of two or more thereof. The total amount of the silane coupling agent is preferably from 0.001 to 5 parts by weight, more preferably from 0.01 to 1 part by weight, even more preferably from 0.02 to 1 part by weight, particularly preferably from 0.05 to 0.6 parts by weight, per 100 parts by weight of the (meth)acrylic polymer. If the content of the silane coupling agent is within the above range, durability is improved and a suitable level of adhering strength to glass and transparent conductive layers is maintained.

The pressure-sensitive adhesive composition may also contain any other known additive within a range not impairing the properties. For example, an antistatic agent (an ionic compound such as an ionic liquid and an alkali metal salt), a colorant, a powder such as a pigment, a dye, a surfactant, a plasticizer, a tackifier, a surface lubricant, a leveling agent, a softening agent, an antioxidant, an anti-aging agent, a light stabilizer, an ultraviolet absorbing agent, a polymerization inhibitor, an inorganic or organic filler, a metal powder, or a particle- or foil-shaped material may be added as appropriate depending on the intended use. A redox system including an added reducing agent may also be used in the controllable range. These additives are preferably used in an amount of 5 parts by weight or less, more preferably 3 parts by weight or less, even more preferably 1 part by weight or less, per 100 parts by weight of the (meth)acrylic polymer.

### <Pressure-Sensitive Adhesive Layer>

The optical pressure-sensitive adhesive layer of the present invention is an optical pressure-sensitive adhesive layer formed from a pressure-sensitive adhesive composition containing a (meth)acrylic polymer and has a gel fraction of 70% or more. Considering the durability test at high temperature assuming particularly for in-vehicle use, the gel fraction of the optical pressure-sensitive adhesive layer is preferably 75% or more, more preferably 80% or more, even more preferably 85% or more, most preferably 90% or more. When the gel fraction is less than 70%, a segregation amount of the uncrosslinked polymer or oligomer increases in the vicinity of the interface between the pressure-sensitive adhesive layer and the adherend (for example, ITO or the like) increases and it is presumed that a fragile layer is formed in the pressure-sensitive adhesive layer. However, when the pressure-sensitive adhesive layer is exposed to a heating/humidification environment, destruction of the pressure-sensitive adhesive layer occurs in the vicinity of the fragile layer, so that foaming and peeling are likely to occur, which is not preferable.

The optical pressure-sensitive adhesive layer of the present invention is an optical pressure-sensitive adhesive layer formed from a pressure-sensitive adhesive composition containing a (meth)acrylic polymer and has a creep value (in the case where the thickness of the pressure-sensitive adhesive layer is 20 μm) of 55 μm or more when a load of 500 g is applied to the optical pressure-sensitive adhesive layer for 1 hour in an environment of 115° C. In particular, in view of durability, the creep value is preferably 65 μm or more, more preferably 100 μm or more, even more preferably 150 μm or more, particularly preferably 200 μm or more. When the creep value is less than 55 μm, it becomes difficult to relax the stress of the pressure-sensitive adhesive layer due to deformation of the adherend (optical film) used by sticking the pressure-sensitive adhesive layer, and when the pressure-sensitive adhesive layer is exposed to a heating/humidification environment, peeling tends to occur easily, which is not preferable. The creep value is preferably 1000 m or less, more preferably 800 μm or less, still more preferably 500 μm or less. When the creep value exceeds 1000 μm, foaming is likely to occur when the pressure-sensitive adhesive layer is exposed to a heating/humidification environment, which is not preferable. In addition, when the gel fraction of the pressure-sensitive adhesive layer is increased, the pressure-sensitive adhesive layer generally becomes hard. However, by designing the creep value to a high value, stress relaxation becomes favorable and even when deformation such as shrinkage of the adherend (optical film) occurs, the deformation of the pressure-sensitive adhesive layer is suppressed, and even when the pressure-sensitive adhesive layer is exposed to a heating/humidification environment, it is possible to suppress foaming, peeling or the like, which is preferable.

In addition, by designing both the gel fraction and the creep value to predetermined values, the optical pressure-sensitive adhesive layer of the present invention can achieve high durability which could not be achieved with conventional pressure-sensitive adhesives. That is, by increasing the gel fraction, stress relaxation of the pressure-sensitive adhesive layer is enhanced while suppressing formation of a fragile layer at the interface between the adherend and the pressure-sensitive adhesive layer, and stress generated at the interface is reduced. As a result, even when dimensional shrinkage of the optical film occurs in the durability test at high temperature, the pressure-sensitive adhesive layer in which peeling does not occur can be obtained.

The pressure-sensitive adhesive layer is formed from the pressure-sensitive adhesive composition, but in forming the pressure-sensitive adhesive layer, it is preferable to adjust the amount used of the entire crosslinking agent and sufficiently consider the influence of the crosslinking treatment temperature and the crosslinking treatment time.

The crosslinking treatment temperature and the crosslinking treatment time can be adjusted by the crosslinking agent to be used. The crosslinking treatment temperature is preferably 170° C. or less.

The crosslinking treatment may be carried out at the temperature of the drying step of the pressure-sensitive adhesive layer or may be carried out by providing a separate crosslinking treatment step after the drying step.

The crosslinking treatment time can be set in consideration of productivity and workability, but is usually about 0.2 to 20 minutes, preferably about 0.5 to 10 minutes.

### <Pressure-Sensitive Adhesive Layer Attached Optical Film>

The pressure-sensitive adhesive layer attached optical film according to the present invention is preferably one in which the optical pressure-sensitive adhesive layer is formed on at least one side of the optical film. As the optical film, a polarizing film (a polarizing plate), a retardation film, an optical compensation film, a brightness enhancement film, a surface treatment film, a scattering prevention film, a transparent conductive film, and a laminate thereof can be used.

For example, the pressure-sensitive adhesive layer may be formed by a method including applying the pressure-sensitive adhesive composition to a release-treated separator or the like, removing the polymerization solvent and so on by drying to form a pressure-sensitive adhesive layer and then transferring it to an optical film, or by a method including applying the pressure-sensitive adhesive composition to an optical film and removing the polymerization solvent and so on by drying to form a pressure-sensitive adhesive layer on the optical film. In applying the pressure-sensitive adhesive, one or more solvents other than the polymerization solvent may be newly added.

### <Separator>

A silicone release liner is preferably used as the release-treated separator. The pressure-sensitive adhesive composition of the present invention may be applied to such a liner and dried to form a pressure-sensitive adhesive layer. In this process, the pressure-sensitive adhesive may be dried using any appropriate method depending on the purpose. A method of drying by heating the coating film which is the pressure-sensitive adhesive composition is applied is preferably used. The heat drying temperature is preferably from 40° C. to 200° C., more preferably from 50° C. to 180° C., particularly preferably from 70° C. to 170° C. When the heating temperature is set in the above range, a pressure-sensitive adhesive having good adhesive properties can be obtained.

Any appropriate drying time may be used. The drying time is preferably from 5 seconds to 20 minutes, more preferably from 5 seconds to 10 minutes, particularly preferably from 10 seconds to 5 minutes.

Before the pressure-sensitive adhesive layer is formed on the surface of the optical film, an anchor layer may be formed on the surface, or any easy adhesion treatment such as a corona treatment or a plasma treatment may be performed on the surface. The surface of the pressure-sensitive adhesive layer may also be subjected to an easy adhesion treatment.

Various methods may be used to form the pressure-sensitive adhesive layer. Specific examples of such methods include roll coating, kiss roll coating, gravure coating, reverse coating, roll brush coating, spray coating, dip roll coating, bar coating, knife coating, air knife coating, curtain coating, lip coating, extrusion coating with a die coater, and the like.

The thickness of the pressure-sensitive adhesive layer is not particularly limited but is, for example, about 1 to 100 μm, preferably 2 to 50 μm, more preferably 2 to 40 μm, even more preferably 5 to 35 μm.

When the pressure-sensitive adhesive layer is exposed, the pressure-sensitive adhesive layer may be protected with a sheet having undergone release treatment (a separator) before practical use.

Examples of the material for forming the separator include a plastic film such as a polyethylene, polypropylene, polyethylene terephthalate, and polyester film; a porous material such as paper, cloth and nonwoven fabric; and an appropriate thin sheet such as a net, a foamed sheet, a metal foil, and a laminate thereof. In particular, a plastic film is preferably used, because of its good surface smoothness.

The plastic film may be any film capable of protecting the pressure-sensitive adhesive layer, and examples thereof include a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, an ethylene-vinyl acetate copolymer film, and the like.

The thickness of the separator is generally from about 5 to about 200 μm, preferably from about 5 to about 100 μm. If necessary, the separator may be treated with a release agent such as a silicone, fluorine, long-chain alkyl, or fatty acid amide release agent, or may be subjected to release and antifouling treatment with silica powder or to antistatic treatment of coating type, kneading and mixing type, vapor-deposition type, or the like. In particular, if the surface of the separator is appropriately subjected to release treatment such as silicone treatment, long-chain alkyl treatment, and fluorine treatment, the peelability from the pressure-sensitive adhesive layer can be further increased.

The release-treated sheet used in the preparation of the pressure-sensitive adhesive layer attached optical film can be used as a separator for a pressure-sensitive adhesive layer attached optical film, so that the process can be simplified.

### <Image Display Device>

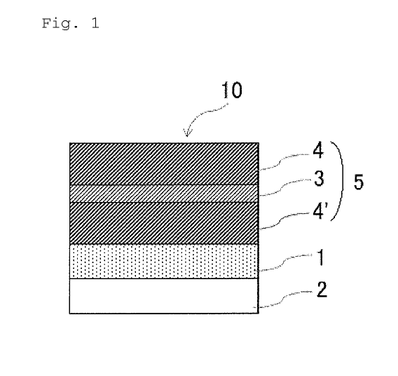

In the image display device of the present invention, it is preferable to use at least one pressure-sensitive adhesive layer attached optical film. As the optical film, a material used for forming an image display device such as a liquid crystal display device or the like is used, and its type is not particularly limited. For example, a polarizing film can be mentioned as the optical film. The polarizing film is a film including a polarizer, and a transparent protective film on one side or both sides of the polarizer can be used (see, for example, FIG. 1).

The polarizer is not particularly limited but various kinds of polarizer may be used. Examples of the polarizer, include a film obtained by uniaxial stretching after a dichromatic substance, such as iodine and dichromatic dye, is adsorbed to a hydrophilic high molecular weight polymer film, such as polyvinyl alcohol-based film, partially formalized polyvinyl alcohol-based film, and ethylene-vinyl acetate copolymer-based partially saponified film, a film polyene-based alignment film, such as dehydrated polyvinyl alcohol and dehydrochlorinated polyvinyl chloride, and the like. Among them, a polarizer composed of a polyvinyl alcohol-based film and a dichroic substance such as iodine is suitable. Thickness of these polarizers is not particularly limited but is generally about 80 μm or less.

A polarizer that is uniaxially stretched after a polyvinyl alcohol-based film dyed with iodine is obtained by stretching a polyvinyl alcohol-based film by 3 to 7 times the original length, after dipped and dyed in an aqueous solution of iodine. If necessary, the polyvinyl alcohol-based film can be immersed in an aqueous solution of potassium iodide or the like which may contain boric acid, zinc sulfate, zinc chloride or the like. Further, if necessary, the polyvinyl alcohol-based film before dyeing may be immersed in water and washed with water. By rinsing polyvinyl alcohol-based film with water, it is possible to clean contamination on the surface of the polyvinyl alcohol-based film and anti-blocking agent, and in addition, the effect of preventing unevenness such as unevenness of dyeing can be exhibited by allowing the polyvinyl alcohol-based film to be swollen. The stretching may be applied after dyeing with iodine or may be applied concurrently, or conversely dyeing with iodine may be applied after stretching. Stretching is applicable in an aqueous solution of boric acid and potassium iodide, or in water bath.

The thickness of the polarizer is preferably 30 μm or less. From the viewpoint of thinning, the thickness is more preferably 25 μm or less, even more preferably 20 μm or less, particularly preferably 15 μm or less.

Such a thin type polarizer has small thickness unevenness, excellent visibility, and small dimensional change, so that the stress applied to the pressure-sensitive adhesive layer becomes smaller even under the heating/humidification conditions, resulting in excellent durability, foaming and peeling hardly occur. As a result, it is further preferable that the thickness of the polarizing film can be reduced.

Typical examples of such a thin polarizer include the thin polarizers disclosed in JP-A-51-069644, JP-A-2000-338329, WO 2010/100917, specification of PCT/JP2010/001460, specification of Japanese Patent Application No. 2010-269002, or specification of Japanese Patent Application No. 2010-263692. These thin polarizers can be obtained by a process including the steps of stretching a laminate of a polyvinyl alcohol-based resin (hereinafter also referred to as PVA-based resin) layer and a stretchable resin substrate and dyeing the laminate. Using this process, the PVA-based resin layer, even when thin, can be stretched without problems such as breakage, which would otherwise be caused by stretching of the layer supported on a stretchable resin substrate.

The thin polarizer should be produced by a process capable of achieving high-ratio stretching to improve polarizing performance, among processes including the steps of stretching and dyeing a laminate. From this point of view, the thin polarizer is preferably obtained by a process including the step of stretching in an aqueous boric acid solution as described in WO 2010/100917 A, PCT/JP2010/001460, Japanese Patent Application No. 2010-269002, or Japanese Patent Application No. 2010-263692, and more preferably obtained by a process including the step of performing auxiliary in-air stretching before stretching in an aqueous boric acid solution as described in Japanese Patent Application No. 2010-269002 or 2010-263692.

A thermoplastic resin with a high level of transparency, mechanical strength, thermal stability, moisture blocking properties, isotropy, and the like may be used as a material for forming a transparent protective film. Examples of such a thermoplastic resin include cellulose resins such as triacetylcellulose, polyester resins, polyethersulfone resins, polysulfone resins, polycarbonate resins, polyamide resins, polyimide resins, polyolefin resins, (meth)acrylic resins, cyclic polyolefin resins (norbornene-based resins), polyarylate resins, polystyrene resins, polyvinyl alcohol resins, and a mixture thereof. The transparent protective film may be bonded with an adhesive layer to one side of the polarizer. On the other side of the polarizer, a thermosetting or ultraviolet-curable resin such as a (meth)acrylic, urethane, acrylic urethane, epoxy, and silicone resin may be used to form the transparent protective film. The transparent protective film may contain any one or more suitable additives. Such additives include, for example, ultraviolet absorbers, antioxidants, lubricants, plasticizers, release agents, anti-coloring agents, flame retardants, nucleating agents, antistatic agents, pigments, and colorants. The content of the thermoplastic resin in the transparent protective film is preferably from 50 to 100% by weight, more preferably from 50 to 99% by weight, even more preferably from 60 to 98% by weight, particularly preferably from 70 to 97% by weight. If the content of the thermoplastic resin in the transparent protective film is 50% by weight or less, high transparency and other properties inherent in the thermoplastic resin may be insufficiently exhibited.

The adhesive used to bond the polarizer to the transparent protective film may be any of various optically-transparent adhesives, such as aqueous adhesives, solvent type adhesives, hot melt type adhesives, radical-curable type adhesives, and cationically curable type adhesives, among which aqueous adhesives or radical-curable type adhesives are preferred.

Examples of the optical film include a reflector, a transflector, a retardation film (including a wavelength plate such as a half or quarter wavelength plate), a viewing angle compensation film, a brightness enhancement film, and any other optical layer that can be used to form liquid crystal display devices or other devices. They may be used alone as the optical film, or one or more layers of any of them may be used together with the polarizing film to form a laminate for practical use.

The optical film including a laminate of the polarizing film and the optical layer may be formed by a method of laminating them one by one in the process of manufacturing a liquid crystal display device or the like. However, an optical film formed in advance by lamination is advantageous in that it can facilitate the process of manufacturing a liquid crystal display device or the like because it has stable quality and good assembling workability. In the lamination, any appropriate bonding means such as a pressure-sensitive adhesive layer may be used. When the polarizing film and any other optical layer are bonded together, their optical axes may be each aligned at an appropriate angle, depending on the desired retardation properties or other desired properties.

The pressure-sensitive adhesive layer attached optical film according to the present invention is preferably used to form liquid crystal display devices or other various image display devices. Liquid crystal display devices may be formed according to conventional techniques. Namely, a liquid crystal display device may be typically formed by appropriately assembling a display panel such as a liquid crystal cell, a pressure-sensitive adhesive layer attached optical film, and a component such as a lighting system as needed, and incorporating a driving circuit according to any conventional techniques, as long as the pressure-sensitive adhesive layer attached optical film according to the present invention is used. The liquid crystal cell to be used may also be of any type such as TN type, STN type, π type, VA type, or IPS type.

An appropriate liquid crystal display device such as a liquid crystal display device in which a pressure-sensitive adhesive layer attached optical film is disposed on one side or both sides of a display panel such as a liquid crystal cell, or a liquid crystal display device using a backlight or a reflector in a lighting system can be formed. In that case, the pressure-sensitive adhesive layer attached optical film according to the present invention can be disposed on one side or both sides of a display panel such as a liquid crystal cell. When optical films are provided on both sides, they may be the same as or different from each other. Furthermore, in assembling a liquid crystal display, suitable parts, such as diffusion layer, anti-glare layer, antireflection film, protective plate, prism array, lens array sheet, optical diffusion sheet, and backlight, may be disposed in suitable position in one layer or two or more layers.

### EXAMPLES

The present invention is specifically described by Examples below, which are not intended to limit the scope of the present invention. In each Example, parts and percentages are all on a weight basis. Unless otherwise stated below, the conditions of room temperature standing are 23° C. and 65% RH in all the cases.

### <Measurement of Weight Average Molecular Weight (Mw) of (Meth)Acrylic Polymer>

The weight average molecular weight (Mw) of the (meth)acrylic polymer was measured by GPC (gel permeation chromatography). The polydispersity (Mw/Mn) of the (meth)acrylic polymer was also determined using the same method.
Analyzer: HLC-8120 GPC, manufactured by TOSOH CORPORATION
Columns: G7000 H_{XL}+GM H_{XL}+GM H_{XL}, manufactured by TOSOH CORPORATION
Column size: each 7.8 mmφ×30 cm, 90 cm in total
Column temperature: 40° C.
Flow rate: 0.8 ml/minute
Injection volume: 100 μl
Eluent: 10 mM phosphoric acid/tetrahydrofuran
Detector: differential refractometer (RI)
Standard sample: polystyrene

### <Preparation of Polarizing Film (Polarizing Plate)>

An 80-μm-thick polyvinyl alcohol film was stretched to 3 times between rolls different in velocity ratio while the film was dyed in a 0.3% iodine solution at 30° C. for 1 minute. The film was then stretched to a total stretch ratio of 6 times while the film was immersed in an aqueous solution containing 4% of boric acid and 10% of potassium iodide at 60° C. for 0.5 minutes. Subsequently, the film was washed by immersion in an aqueous solution containing 1.5% of potassium iodide at 30° C. for 10 seconds and then dried at 50° C. for 4 minutes to give a 28-μm-thick polarizer. A polarizing film (a polarizing plate) was formed by bonding an 80-μm-thick saponified triacetylcellulose (TAC) films to both sides of the polarizer with a polyvinyl alcohol-based adhesive.

### Example 1

### (Preparation of (Meth)Acrylic Polymer (A1))

A four-necked flask equipped with a stirring blade, a thermometer, a nitrogen gas inlet tube and a condenser was charged with a monomer mixture containing 99 parts of butyl acrylate and 1 part of 4-hydroxybutyl acrylate. Further, 0.1 parts of 2,2′-azobisisobutyronitrile as a polymerization initiator was added thereto together with 85 parts of ethyl acetate and 15 parts of toluene to 100 parts of the monomer mixture, and nitrogen gas was introduced with gentle stirring to purge the inside of the flask and polymerization reaction was carried out for 30 minutes while maintaining the liquid temperature in the flask at around 55° C. to prepare a solution of a (meth)acrylic polymer (A1) having a weight average molecular weight (Mw) of 1,440,000 and a ratio Mw/Mn of 1.75.

### (Preparation of Pressure-Sensitive Adhesive Composition)

A solution of an acrylic pressure-sensitive adhesive composition was prepared by blending 0.2 parts of an isocyanate-based crosslinking agent (TAKENATE D-160N, trimethylolpropane hexamethylene diisocyanate, manufactured by Mitsui Chemicals, Inc.) and 0.2 parts of a silane coupling agent (X-41-1810, a thiol group-containing silicate oligomer, manufactured by Shin-Etsu Chemical Co., Ltd.) with respect to 100 parts of the solid content in the solution of the obtained (meth)acrylic polymer (A1).

### (Production of Pressure-Sensitive Adhesive Layer Attached Polarizing Film)

Next, the solution of the acrylic pressure-sensitive adhesive composition was applied onto one side of a polyethylene terephthalate film (separator film: MRF 38, manufactured by Mitsubishi Chemical Polyester Film Co., Ltd.) treated with a silicone-based releasing agent so that the pressure-sensitive adhesive layer after drying has a thickness of 20 μm, and dried at 155° C. for 1 minute to form a pressure-sensitive adhesive layer on the surface of the separator film. Next, the pressure-sensitive adhesive layer formed on the separator film was transferred to the produced polarizing film to prepare a pressure-sensitive adhesive layer attached polarizing film.

### (Preparation of (Meth)Acrylic Polymer (A2))

A solution of a (meth)acrylic polymer (A2) was prepared in the same manner as in (Preparation of (Meth)acrylic Polymer (A1)), except that the polymerization solvents were changed to 70 parts of ethyl acetate and 30 parts of toluene with respect to 100 parts of the monomer mixture (solid content).

### (Preparation of (Meth)Acrylic Polymer (A3))

A solution of a (meth)acrylic polymer (A3) was prepared in the same manner as in (Preparation of (Meth)acrylic Polymer (A1)), except that the charged monomer composition was changed to 83 parts of butyl acrylate, 16 parts of phenoxyethyl acrylate, and 1 part of 4-hydroxybutyl acrylate.

### (Preparation of (Meth)Acrylic Polymer (A4))

A solution of a (meth)acrylic polymer (A4) was prepared in the same manner as in (Preparation of (Meth)acrylic Polymer (A1)), except that the charged monomer composition was changed to 78 parts of butyl acrylate, 16 parts of phenoxyethyl acrylate, 5 parts of N-vinylpyrrolidone, and 1 part of 4-hydroxybutyl acrylate.

### (Preparation of (Meth)Acrylic Polymer (A5))

A solution of a (meth)acrylic polymer (A5) was prepared in the same manner as in (Preparation of (Meth)acrylic Polymer (A1)), except that the charged monomer composition was changed to 95 parts of butyl acrylate and 5 parts of 4-hydroxybutyl acrylate.

### (Preparation of (Meth)Acrylic Polymers (A6), (A7), and (A8))

Solutions of (meth)acrylic polymers (A6), (A7), and (A8) were prepared in the same manner as in (Preparation of (Meth)acrylic Polymer (A1)), except that the monomer mixture shown in Table 1 was charged and the polymerization reaction time was changed to 2 hours.

### (Preparation of (Meth)Acrylic Polymer (A9): Living Radical Polymerization)

A reaction vessel in a glove box purged with argon was charged with 0.035 parts of ethyl 2-methyl-2-n-butyltellanyl-propionate, 0.0025 parts of 2,2′-azobisisobutyronitrile, and 1 part of ethyl acetate, and the reaction vessel was sealed and taken out from the glove box.

Subsequently, 95 parts of butyl acrylate, 5 parts of 4-hydroxybutyl acrylate and 50 parts of ethyl acetate as a polymerization solvent were charged into the reaction vessel while argon gas was flowing into the reaction vessel, and the polymerization reaction was carried out for 20 hours while maintaining the liquid temperature in the reaction vessel at about 60° C., thereby to prepare a solution of a (meth)acrylic polymer (A9).

### (Preparation of (Meth)Acrylic Polymer (A10))

A solution of a (meth)acrylic polymer (A10) was prepared in the same manner as in the (Preparation of (Meth)acrylic Polymer (A1)) except that the polymerization reaction time was changed to 6 hours.

### (Preparation of (Meth)Acrylic Polymer (A11))

A solution of a (meth)acrylic polymer (A11) was prepared in the same manner as in the (Preparation of (Meth)acrylic Polymer (A5)) except that the polymerization reaction time was changed to 6 hours.

### (Preparation of (Meth)Acrylic Polymer (A12): Living Radical Polymerization)

A reaction vessel in a glove box purged with argon was charged with 0.064 parts of ethyl 2-methyl-2-n-butyltellanyl-propionate, 0.0046 parts of 2,2′-azobisisobutyronitrile, and 1 part of ethyl acetate, and the reaction vessel was sealed and taken out from the glove box.

Subsequently, 99 parts of butyl acrylate, 1 part of 4-hydroxybutyl acrylate, and 50 parts of ethyl acetate as a polymerization solvent were charged into the reaction vessel while argon gas was flowing into the reaction vessel, and the polymerization reaction was carried out for 20 hours while maintaining the liquid temperature in the reaction vessel at about 60° C., thereby to prepare a solution of a (meth)acrylic polymer (A12).

### Examples 2 to 18 and Comparative Examples 1 to 5

In Examples 2 to 18 and Comparative Examples 1 to 5, solutions of (meth)acrylic polymers (A2) to (A12) having polymer physical properties (weight average molecular weight (MW) and polydispersity (Mw/Mn)) shown in Table 1 were prepared in the same manner as in Example 1, except that the preparation method of the (meth)acrylic polymers (A2) to (A12) and the kind and blending ratio of such monomers were changed and the production conditions were controlled as shown in Table 1.

Further, a solution of the acrylic pressure-sensitive adhesive composition was prepared in the same manner as in Example 1, except that the kind of the crosslinking agent or the amount of the crosslinking agent used was changed as shown in Table 1 with respect to the obtained solution of each (meth)acrylic polymer. Further, a pressure-sensitive adhesive layer attached polarizing f ilm was prepared in the same manner as in Example 1 using the solution of the acrylic pressure-sensitive adhesive composition.

The pressure-sensitive adhesive layer attached polarizing film obtained in the above Examples and Comparative Examples were evaluated as follows. The evaluation results are shown in Table 2.

### <Measurement of Gel Fraction>

Approximately 0.1 g of the optical pressure-sensitive adhesive layer formed on the release treated surface of the separator film within 1 minute after preparation was scraped to obtain a sample 1. The sample 1 was wrapped in a Teflon (registered trademark) film (trade name “NTF 1122”, manufactured by Nitto Denko Corporation) having a diameter of 0.2 μm and then bound with a kite string, and this was used as a sample 2. The weight of the sample 2 before being subjected to the following test was measured and this was taken as a weight A. The weight A is a total weight of the sample 1 (pressure-sensitive adhesive layer), the Teflon (registered trademark) film, and the kite string. Further, the total weight of the Teflon (registered trademark) film and the kite string is defined as a weight B. Then, the sample 2 was placed in a 50 ml container filled with ethyl acetate and left standing at 23° C. for 1 week. Thereafter, the sample 2 was taken out from the container, and dried in a dryer at 130° C. for 2 hours to remove ethyl acetate, and then the weight of the sample 2 was measured. The weight of the sample 2 after being subjected to the above test was measured and this was taken as a weight C. The gel fraction is calculated from the following formula:

Gel fraction (%)=(C−B)/(A−B)×100

The gel fraction of the optical pressure-sensitive adhesive layer of the present invention is 70% or more, preferably 75% or more, even more preferably 80% or more, still even more preferably 85% or more, most preferably 90% or more.

### <Measurement Method of Creep Value>

An upper end portion of 10 mm×10 mm of a pressure-sensitive adhesive optical film (thickness of the pressure-sensitive adhesive adhesive layer: 20 μm) cut into a size of 10 mm×30 mm was attached to a SUS plate with a pressure-sensitive adhesive layer interposed therebetween and autoclaved under conditions of 50° C. and 5 atm for 15 minutes. The precision hot plate set so that the heating surface is vertical was heated to 115° C. and the SUS plate to which the pressure-sensitive adhesive optical film was attached was placed so that the surface to which the pressure-sensitive adhesive optical film was not attached is in contact with the heating surface of the hot plate. After 5 minutes from the start of heating the SUS plate at 115° C., a deviation width between the pressure-sensitive adhesive optical film and the SUS plate before and after loading was measured by applying a load of 500 g for 1 hour to the lower end portion of the pressure-sensitive adhesive optical film, thereby to obtain a creep value (μm) at 115° C. (thickness of the pressure-sensitive adhesive layer: 20 μm).

The creep value (thickness of the pressure-sensitive adhesive layer: 20 μm) of the optical pressure-sensitive adhesive layer of the present invention when a load of 500 g is applied in an environment of 115° C. for 1 hour is 55 μm or more, preferably 65 μm or more, more preferably 100 m or more, even more preferably 150 μm or more, particularly preferably 200 μm or more. Further, the creep value is preferably 1000 μm or less, more preferably 800 μm or less, even more preferably 500 μm or less.

### <Durability Test Against ITO Glass>

A pressure-sensitive adhesive layer attached polarizing film cut into a size of 37 inches was used as a sample. An amorphous ITO layer was formed on an alkali-free glass (EG-XG, manufactured by Corning Incorporated) having a thickness of 0.7 mm and the sample was used as an adherend, and the pressure-sensitive adhesive layer attached polarizing film was attached to the surface of the amorphous ITO layer using a laminator. Then, autoclave treatment was carried out at 50° C. and 0.5 MPa for 15 minutes to completely adhere the sample to the adherend. The sample subjected to such treatment was subjected to a treatment for 500 hours in each environment of 95° C., 105° C., 65° C./95% RH, and then the appearance between the polarizing film and the amorphous ITO was visually observed according to the following criteria to evaluate the durability against ITO glass. The ITO layer was formed by sputtering. An Sn ratio of the composition of ITO was 3% by weight, and a heating step of 140° C.×60 minutes was carried out before bonding the samples. The Sn ratio of ITO was calculated from the weight of Sn atoms/(weight of Sn atoms+weight of In atoms).

### (Evaluation Criteria)

⊙: No change in appearance of foaming or peeling occurs at all.
◯: Slight peeling or foaming at the end portion occurs, but there is no practical problem.
Δ: Peeling or foaming at the end portion occurs, but there is no practical problem except for special applications (for example, a display with a narrow frame with a short distance from the end portion of the polarizing film to the active area where the image is displayed).
x: Significant peeling occurs at the end portion, causing problems in practical use.
Peeling: The term “peeling” means that evaluation of foaming could not be performed because significant peeling occurred.

In these cases, there is a problem in practical use.

TABLE 1

| | | | | | | | Polymer | | | | |
|---|---|---|---|---|---|---|---|---|---|---|---|
| | (Meth) | | | | | | physical | | | | Silane |
| | acrylic | Composition of polymer | | | | | properties | | Crosslinking agent | | coupling |
| | polymer | BA | PEA | NVP | HBA | AA | Mw | Mw/Mn | Isocyanate | Peroxide | agent |
| Example 1 | (A1) | 99 | | | 1 | | 1.44 | 1.75 | 0.2 | — | 0.2 |
| | | | | | | | million | | | | |
| Example 2 | (A1) | 99 | | | 1 | | 1.44 | 1.75 | 0.3 | — | 0.2 |
| | | | | | | | million | | | | |
| Example 3 | (A1) | 99 | | | 1 | | 1.44 | 1.75 | 0.03 | 0.3 | 0.2 |
| | | | | | | | million | | | | |
| Example 4 | (A1) | 99 | | | 1 | | 1.44 | 1.75 | 0.03 | 0.3 | 0.2 |
| | | | | | | | million | | | | |
| Example 5 | (A1) | 99 | | | 1 | | 1.44 | 1.75 | 0.03 | 0.3 | 0.2 |
| | | | | | | | million | | | | |
| Example 6 | (A1) | 99 | | | 1 | | 1.44 | 1.75 | 0.03 | 0.3 | 0.2 |
| | | | | | | | million | | | | |
| Example 7 | (A1) | 99 | | | 1 | | 1.44 | 1.75 | 0.06 | 0.3 | 0.2 |
| | | | | | | | million | | | | |
| Example 8 | (A1) | 99 | | | 1 | | 1.44 | 1.75 | 0.1 | 0.3 | 0.2 |
| | | | | | | | million | | | | |
| Example 9 | (A1) | 99 | | | 1 | | 1.44 | 1.75 | 0.15 | 0.3 | 0.2 |
| | | | | | | | million | | | | |
| Example 10 | (A2) | 99 | | | 1 | | 0.95 | 1.55 | 0.4 | — | 0.2 |
| | | | | | | | million | | | | |
| Example 11 | (A2) | 99 | | | 1 | | 0.95 | 1.55 | 0.2 | 0.3 | 0.2 |
| | | | | | | | million | | | | |
| Example 12 | (A3) | 83 | 16 | | 1 | | 1.35 | 1.88 | 0.1 | 0.3 | 0.2 |
| | | | | | | | million | | | | |
| Example 13 | (A4) | 78 | 16 | 5 | 1 | | 1.40 | 1.81 | 0.1 | 0.3 | 0.2 |
| | | | | | | | million | | | | |
| Example 14 | (A5) | 95 | | | 5 | | 1.85 | 2.16 | 0.03 | 0.3 | 0.2 |
| | | | | | | | million | | | | |
| Example 15 | (A6) | 78 | 16 | 5 | 1 | | 1.74 | 2.78 | 0.1 | 0.3 | 0.2 |
| | | | | | | | million | | | | |
| Example 16 | (A7) | 77.95 | 16 | 5 | 1 | 0.05 | 1.65 | 2.53 | 0.1 | 0.3 | 0.2 |
| | | | | | | | million | | | | |
| Example 17 | (A8) | 77.8 | 16 | 5 | 1 | 0.2 | 1.70 | 2.61 | 0.1 | 0.3 | 0.2 |
| | | | | | | | million | | | | |
| Example 18 | (A9) | 95 | | | 5 | | 1.85 | 1.89 | 0.1 | 0.3 | 0.2 |
| | | | | | | | million | | | | |
| Comparative | (A10) | 99 | | | 1 | | 1.79 | 4.15 | 0.05 | — | 0.2 |
| Example 1 | | | | | | | million | | | | |
| Comparative | (A10) | 99 | | | 1 | | 1.79 | 4.15 | 0.2 | 0.3 | 0.2 |
| Example 2 | | | | | | | million | | | | |
| Comparative | (A11) | 95 | | | 5 | | 1.95 | 4.01 | 0.05 | — | 0.2 |
| Example 3 | | | | | | | million | | | | |
| Comparative | (A11) | 95 | | | 5 | | 1.95 | 4.01 | 0.1 | 0.3 | 0.2 |
| Example 4 | | | | | | | million | | | | |
| Comparative | (A12) | 99 | | | 1 | | 0.86 | 1.45 | 0.5 | — | 0.2 |
| Example 5 | | | | | | | million | | | | |

Abbreviations and the like in Table 1 are described below.

BA: Butyl acrylate
PEA: Phenoxyethyl acrylate

### NVP: N-Vinyl-pyrrolidone

HBA: 4-Hydroxybutyl acrylate
AA: Acrylic acid
Isocyanate: TAKENATE D-160N (an adduct of trimethylolpropane with hexamethylene diisocyanate), manufactured by Mitsui Chemicals Inc.
Peroxide: NYPER BMT (benzoyl peroxide), manufactured by NOF Corporation
Silane coupling agent: X-41-1810 (a thiol group-containing silicate oligomer), manufactured by Shin-Etsu Chemical Co., Ltd.

TABLE 2

| | | | | Durability | | | | | |
|---|---|---|---|---|---|---|---|---|---|
| | Gel | 115° C. | Polarizer | 95° C. | | 105° C. | | 65° C. 95% RH | |
| | fraction | Creep | thickness | Foaming | Peeling | Foaming | Peeling | Foaming | Peeling |
| Example 1 | 74.0 | 211 | 28 | Δ | Δ | Δ | Δ | ⊙ | ◯ |
| Example 2 | 79.0 | 116 | 28 | ◯ | Δ | Δ | Δ | ⊙ | ◯ |
| Example 3 | 83.5 | 342 | 28 | ⊙ | ◯ | ◯ | Δ | ⊙ | ◯ |
| Example 4 | 83.5 | 342 | 22 | ⊙ | ◯ | ◯ | ◯ | ⊙ | ◯ |
| Example 5 | 83.5 | 342 | 18 | ⊙ | ⊙ | ⊙ | ◯ | ⊙ | ⊙ |
| Example 6 | 83.5 | 342 | 12 | ⊙ | ⊙ | ⊙ | ⊙ | ⊙ | ⊙ |
| Example 7 | 85.8 | 248 | 28 | ⊙ | ⊙ | ◯ | Δ | ⊙ | ◯ |
| Example 8 | 89.3 | 168 | 28 | ⊙ | ⊙ | ◯ | ◯ | ⊙ | ◯ |
| Example 9 | 92.2 | 144 | 28 | ⊙ | ⊙ | ◯ | ◯ | ⊙ | ◯ |
| Example 10 | 79.6 | 68 | 28 | ⊙ | Δ | ◯ | Δ | ⊙ | ◯ |
| Example 11 | 87.8 | 110 | 28 | ⊙ | ◯ | ⊙ | ◯ | ⊙ | ◯ |
| Example 12 | 88.7 | 156 | 28 | ⊙ | ⊙ | ⊙ | ◯ | ⊙ | ◯ |
| Example 13 | 89.1 | 156 | 28 | ⊙ | ⊙ | ⊙ | ⊙ | ⊙ | ⊙ |
| Example 14 | 91.9 | 137 | 28 | ⊙ | ⊙ | ⊙ | ⊙ | ⊙ | ⊙ |
| Example 15 | 90.0 | 133 | 28 | ⊙ | ⊙ | ⊙ | ◯ | ⊙ | ⊙ |
| Example 16 | 86.7 | 143 | 28 | ⊙ | ⊙ | ⊙ | ◯ | ⊙ | ⊙ |
| Example 17 | 87.2 | 154 | 28 | ⊙ | ◯ | ⊙ | Δ | ⊙ | ⊙ |
| Example 18 | 92.3 | 121 | 28 | ⊙ | ⊙ | ⊙ | ⊙ | ⊙ | ⊙ |
| Comparative | 60.0 | 401 | 28 | X | ◯ | X | Δ | ⊙ | ◯ |
| Example 1 | | | | | | | | | |
| Comparative | 89.2 | 41 | 28 | ◯ | X | ◯ | X | Peeling | X |
| Example 2 | | | | | | | | | |
| Comparative | 75.3 | 47 | 28 | X | X | X | X | ⊙ | Δ |
| Example 3 | | | | | | | | | |
| Comparative | 93.1 | 30 | 28 | ⊙ | X | ⊙ | X | Peeling | X |
| Example 4 | | | | | | | | | |
| Comparative | 84.2 | 45 | 28 | ◯ | X | ◯ | X | Peeling | X |
| Example 5 | | | | | | | | | |

From the results in Table 2, it was confirmed in Examples that by using an optical pressure-sensitive adhesive layer having a predetermined gel fraction and a creep value, the durability was excellent, and even in applications requiring heat resistance and moisture resistance, the polarizing film was confirmed to be practical. On the other hand, it was confirmed that such durability was inferior in the Comparative Example.

### DESCRIPTION OF REFERENCE SIGNS

1 Pressure-sensitive adhesive layer
2 Separator
3 Polarizer
4, 4′ Protective film
5 Polarizing film (polarizing plate)
10 Pressure-sensitive adhesive layer attached polarizing film

1. An optical pressure-sensitive adhesive layer formed from a pressure-sensitive adhesive composition containing a (meth)acrylic polymer,
wherein the optical pressure-sensitive adhesive layer has a gel fraction of 70% or more and a creep value of 55 μm or more when a load of 500 g is applied to the optical pressure-sensitive adhesive layer for 1 hour under an environment of 115° C.

2. The optical pressure-sensitive adhesive layer according to claim 1, wherein a polydispersity (weight average molecular weight (Mw)/number average molecular weight (Mn)) of the (meth)acrylic polymer is 3.0 or less.

3. The optical pressure-sensitive adhesive layer according to claim 1, wherein a weight average molecular weight (Mw) of the (meth)acrylic polymer is from 900,000 to 3,000,000

4. The optical pressure-sensitive adhesive layer according to claim 1, wherein the pressure-sensitive adhesive composition contains a peroxide-based crosslinking agent.

5. The optical pressure-sensitive adhesive layer according to claim 4, wherein the crosslinking agent is contained in an amount of 0.01 to 3 parts by weight per 100 parts by weight of the (meth)acrylic polymer.

6. The optical pressure-sensitive adhesive layer according to claim 1, wherein the (meth)acrylic polymer contains 0.01 to 7% by weight of a hydroxyl group-containing monomer as a monomer unit.

7. The optical pressure-sensitive adhesive layer according to claim 1, wherein the (meth)acrylic polymer contains 3 to 25% by weight of an aromatic ring-containing monomer as a monomer unit.

8. The optical pressure-sensitive adhesive layer according to claim 1, wherein the (meth)acrylic polymer contains 0.1 to 20% by weight of an amide group-containing monomer as a monomer unit.

9. The optical pressure-sensitive adhesive layer according to claim 8, wherein the amide group-containing monomer is an N-vinyl group-containing lactam-based monomer.

10. The optical pressure-sensitive adhesive layer according to claim 1, wherein the pressure-sensitive adhesive composition contains an organic tellurium compound.

11. A method for producing the optical pressure-sensitive adhesive layer according to claim 1, wherein the (meth)acrylic polymer is produced by living radical polymerization.

12. A pressure-sensitive adhesive layer attached optical film, comprising the optical pressure-sensitive adhesive layer according to claim 1 on at least one side of an optical film.

13. The pressure-sensitive adhesive layer attached optical film according to claim 12, wherein
the optical film is a polarizing film; the polarizing film contains a polarizer, and
the polarizer has a thickness of 30 μm or less.

14. An image display device comprising at least one pressure-sensitive adhesive layer attached optical film according to claim 12.
